(19) United States
(12) Patent Application Publication
(10) Pub. No.: US 2025/0140745 A1
(43) Pub. Date: May 1, 2025

(54) DIE WITH CONNECTION PAD

(71) Applicant: TEXAS INSTRUMENTS INCORPORATED, DALLAS, TX (US)

(72) Inventors: JOSE ARVIN PLOMANTES, DAGUPAN (PH); JEFFREY SOLAS, ILOILO CITY (PH)

(21) Appl. No.: 18/498,827

(22) Filed: Oct. 31, 2023

(51) Int. Cl. H01L 25/065; H01L 23/00

(52) U.S. Cl. CPC H01L 25/0655; H01L 24/05; H01L 24/37; H01L 24/40; H01L 24/48; H01L 24/73; H01L 2224/0599; H01L 2224/37147; H01L 2224/40106; H01L 2224/40177; H01L 2224/48106

(57) ABSTRACT

An IC (integrated circuit) package include an interconnect having a die attach pad and lead. The IC package also includes a die with a first side mounted on the die attach pad and a second side opposing the first side. The second side having a planar region. The planar region having selective polyimide structures between contact points of a connection pad. The IC package also includes a clip coupled to the connection pad and to a lead of the leads.

### TECHNICAL FIELD

This description relates to a die with a connection pad.

### BACKGROUND

In the context of IC (integrated circuit) packages, a die refers to the individual silicon wafer on which the integrated circuitry is fabricated, providing a core component of an IC package. The term die is derived from the fact that these individual silicon wafers are typically separated or diced from a larger semiconductor wafer during the manufacturing process. The manufacturing of IC packages involves the deposition, etching, and layering of various materials on the silicon wafer to create the transistors, capacitors, interconnections and other components that form the IC package. Responsive to fabricating circuitry on the wafer, the wafer is diced into individual pieces, and these individual pieces are referred to as dies. These individual dies are then packaged into plastic or ceramic packages with external pins or leads to protect them and provide a way for connecting the IC package to other components in an electronic circuit, such as a printed circuit board (PCB). The packaging also helps dissipate heat and protect the IC package from environmental factors.

### SUMMARY

A first example relates to an IC (integrated circuit) package including an interconnect having a die attach pad and leads. The IC package includes a die with a first side mounted on the die attach pad and a second side opposing the first side. The second side has a planar region, the planar region having selective polyimide structures between contact points of a connection pad. A clip of the IC package is coupled to the connection pad and to a lead of the leads.

A second example relates to a wafer including dies having a first side and a second side opposing the first side. The second side of the dies have a planar region. The planar region has selective polyimide structures between contact points of a connection pad.

A third example relates to a method for forming an IC (integrated circuit) package including applying a coating of selective polyimide film on a wafer including dies with a contact pad. The method includes selectively removing regions of the selective polyimide film to form selective polyimide structures and sputtering a metal layer responsive to the selective removing of the regions of the selective polyimide film. The method also includes applying a photoresist coat on the metal layer and selectively removing portions of the photoresist coat to expose portions of the metal layer that overly the contact pad of the dies. The method includes electroplating the portions of the metal layer that overlay the contact pad of the dies to form contact points for connection pads for the dies of the wafer, such that selective polyimide structures are between the contact points of the connection pad of the dies. The method further includes stripping a remainder of the photoresist coat and etching portions of the metal layer that overlay the selective polyimide structures to provide a planar region for the dies of the wafer.

### BRIEF DESCRIPTION OF THE DRAWINGS

FIG. 1A illustrates a cross-section view of an IC (integrated circuit) package that includes a connection pad.

FIG. 1B illustrates an overhead view of the IC package of FIG. 1A.

FIG. 2 illustrates an example of a wafer that is employable to provide the die of FIGS. 1A and 1B.

FIG. 3 illustrates another example of a wafer that is employable to provide the die of FIGS. 1A and 1B.

FIGS. 4-15 illustrate stages of a method for fabricating a wafer.

FIGS. 16, 17A, 17B, 18A, 18B and 19 illustrate stages of a method for fabricating an IC package.

FIG. 20 is a flowchart of an example method for forming an IC package.

### DETAILED DESCRIPTION

This description is related to an integrated circuit (IC) package and a method for forming the IC package. The IC package has an interconnect (e.g., a lead frame) with a die attach pad and leads, and a die with two sides (e.g., two surfaces). One side of the die has a planar region (e.g., a planar surface) containing selective polyimide structures between contact points of a connection pad. A clip connects the connection pad to one of the leads. Solder paste (or other conductive adhesive) can be applied over the selective polyimide structures and contact points of the connection pad to adhere the clip to the connection pad. The planar region ensures that the solder paste flows relatively evenly over the selective polyimide structures and the contact points to facilitate a reliable connection between the connection pad and the clip.

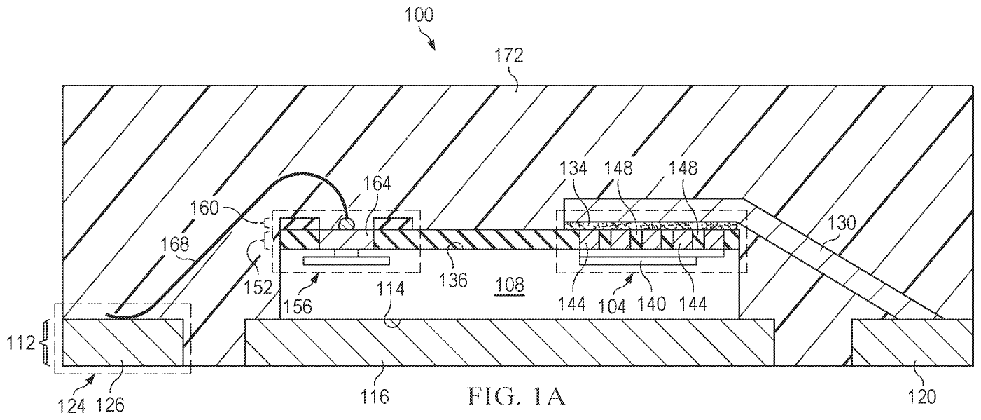

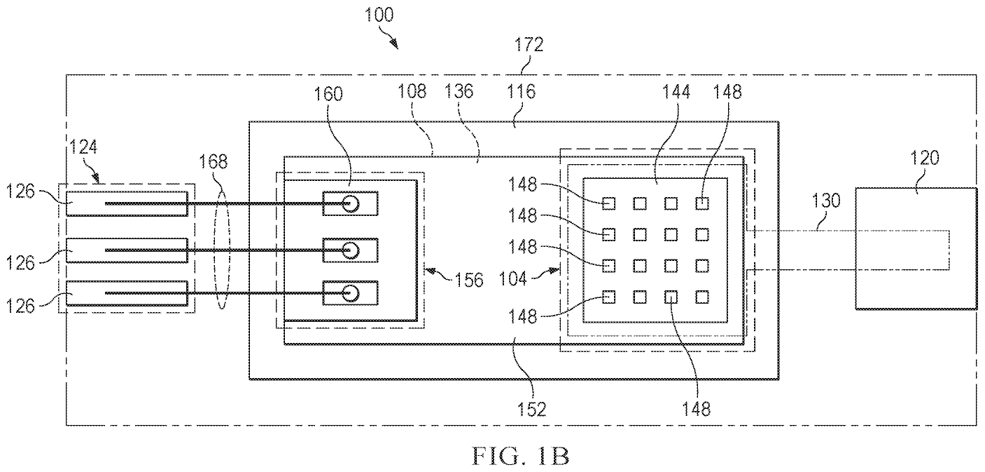

FIG. 1A illustrates a cross-section view of an IC (integrated circuit) package 100 that includes a connection pad 104. FIG. 1B illustrates an overhead view of the IC package 100. Thus, FIGS. 1A and 1B employ the same reference numbers to denote the same features. The IC package 100 includes a die 108 mounted on an interconnect 112. More specifically, a first side 114 of the die 108 is mounted on a die attach pad 116 of the interconnect 112. In some examples, the interconnect 112 is alternatively referred to as a lead frame. The interconnect 112 includes a first lead 120 and a set of leads 124. In the example illustrated, there are three (3) leads 126 in the set of leads 124, but in other examples, there are more or less leads 126 in the set of leads 124.

In some examples, the first lead 120 is a high-power lead, such as a lead configured to support a connection with a voltage of 650 volts (V) or more. In other examples, the first lead 120 is a low power lead. The first lead 120 is coupled to the connection pad 104 of the die 108 through a clip 130. The clip 130 is attached to the connection pad 104 with a conductive adhesive 134, such as solder paste. The clip 130 is formed of a conductive material, such as copper. In FIG. 1B, the clip 130 is shown as being transparent, and the conductive adhesive 134 is omitted to reveal details of the connection pad 104.

The connection pad 104 provides a planar region on a second side 136 of the die 108. The connection pad 104 provides a galvanic path (e.g., a conductive path) to a circuit module 140 of the die 108. The circuit module 140 represents a circuit embedded in the die 108. In some examples, the connection pad 104 is a BOAC (bond over active circuit) connection pad. In some examples, the circuit module 140 includes a field effect transistor (FET). The connection pad 104 is formed a planar arrangement of metal connection points 144 (only some of which are labeled). The metal connection points are formed of copper (Cu) in some examples. In other examples, the metal connection points 144 are formed of copper (Cu), nickel (Ni) and Palladium (Pd). In examples there the circuit module 140 is a FET, the metal connection points 144 could connect to a source or drain of the FET. The metal connection points 144 are arranged in a cross-hatch pattern, and selective polyimide structures 148 (only some of which are labeled) are arranged between the connection points 144. Moreover, the cross-hatch pattern of the metal connection points 144 curtails wafer warpage. The selective polyimide structures 148 have a relatively square shape, and in some examples, the selective polyimide structures 148 have a length and width of about 10 to about 40 micrometers (μm). In other examples, the selective polyimide structures 148 have a rectangular shape.

The selective polyimide structures 148 are formed of polyimide and protrude through the metal connection points 144 such that the connection pad 104 is a planar region. The selective polyimide structures 148 are formed with a selective polyimide film 152. In some examples, other portions of the second side 136 are also covered by the selective polyimide film 152. As noted, the connection pad 104, formed with the metal connection points 144 and the selective polyimide structures 148 between the metal connection points 144 provide a planar region of the second side 136. This planar region facilitates even distribution of the conductive adhesive 134 over the connection pad 104. Absent the selective polyimide structures 148, the conductive adhesive 134 would flow unevenly into voids left between the metal connection points 144.

The selective polyimide film 152 (or more simply, a polyimide film) is formed with a polyimide material. The polyimide film is a synthetic polymer with a stable and heat-resistant molecular structure. The selective polyimide film 152 is an insulative material.

A wire bond region 156 is spaced apart from the planar region formed with the connection pad 104. The wire bond region 156 has a second layer of selective polyimide film 160. The second layer of selective polyimide film 160 overlays the selective polyimide film 152, which can alternatively be referred to as a first layer of selective polyimide film 152. The wire bond region 156 has sections of the second selective polyimide film 160 that circumscribe connection pads 164, which connection pads 164 are low power connection pads in some examples (e.g., 24 V or less). Moreover, wire bonds 168 couple the connection pads 164 to the leads 126 of the set of leads 124. Moreover, although there are three (3) connection pads illustrated in FIG. 1B, in other examples, there are more or less connection pads. As illustrated in FIG. 1A, the connection pad and the second layer selective polyimide film 160 have a non-planar surface, in contrast to the connection pad 104.

A mold compound 172 encapsulates the interconnect 112, the die 108, the clip 130 and the wire bonds 168. The mold compound 172 is implemented with plastic or another polymer in some examples.

By implementing the die 108 with the connection pad 104, the planar region formed by a combination of the metal connection points 144 and the selective polyimide structures 148 is provided. This planar region enables improved conductive area between the circuit module 140 and the first lead 120 through the clip 130. Accordingly, the failure rate of the IC package 100 is curtailed.

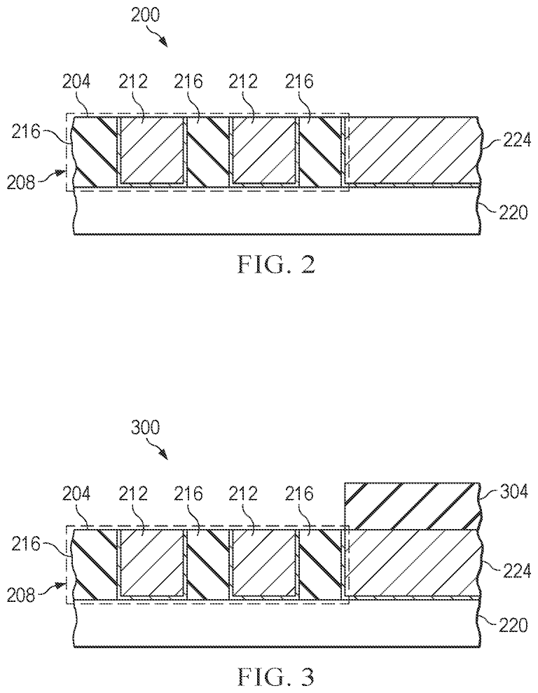

FIG. 2 illustrates an example of a wafer 200 that is employable to provide (through singulation), the die 108 of FIGS. 1A and 1B. The wafer 200 has a planar surface 204 that includes a connection pad 208, such as the connection pad 104 of FIGS. 1A and 1B. The connection pad 208 includes connection points 212 with interleaving selective polyimide structures 216. The planar surface 204 overlays a circuit and substrate layer 220 of the wafer 200. The connection pad 208 connects to a circuit module of the circuit and substrate layer 220 of the wafer 200.

The wafer 200 also includes a metal plated region 224. In various examples, the metal plated region 224 extends the planar surface 204, such that an entire top portion of the wafer 200 is a planar surface in the example illustrated in FIG. 2.

The selective polyimide structures 216 and the connection points 212 of the connection pad 208 have an interleaving structure. More particularly, the connection points 212 have a cross-hatch pattern, and the selective polyimide structures 216 are between contact points of a connection pad, in a manner illustrated in FIG. 1B. Moreover, a planar region of the planar surface 204 provided by the connection pad 208 enables a clip (e.g., the clip 130 of FIGS. 1A and 1B) to be attached to the connection pad 208 with a conductive adhesive (e.g., the conductive adhesive 134 of FIGS. 1A and 1B) flowing relatively evenly thereon. That is, the selective polyimide structures 216 prevents a flow of such conductive adhesive beyond the planar surface 204. Furthermore, the cross-hatch pattern of the connection points 212 (rather than a continuous plate) curtails warpage of the wafer 200.

FIG. 3 illustrates another example of a wafer that is employable to provide (through singulation), the die 108 of FIGS. 1A and 1B. FIGS. 2 and 3 employ the same reference numbers to denote the same structures. Additionally, some reference numbers are not-reintroduced for purposes of brevity. In the wafer 300, the selective polyimide structures 216 are formed with a first selective polyimide film. Moreover, the wafer 300 includes a second selective polyimide film 304 that overlays a portion of the planar surface 204. The second selective polyimide film 304 is employable to implement the second selective polyimide film 160 of FIGS. 1A and 1B. Thus, the wafer 300 has a planar region that includes (but is not limited to) the connection pad 208, and a non-planar region that includes (but is not limited to) the metal plated region 224. Moreover, the non-planar region is spaced apart from the connection pad 208 (a portion of the planar region).

By implementing the wafer 300, the benefits of the wafer 200 of FIG. 2 are realized (e.g., the connection pad 208 has a planar surface that does not cause warpage of the wafer 300), while allowing features such as the connection pads 164 of the wire bond region 156 (that do not benefit from a planar surface) to be realized on the same die (e.g., the die 108 of FIGS. 1A and 1B).

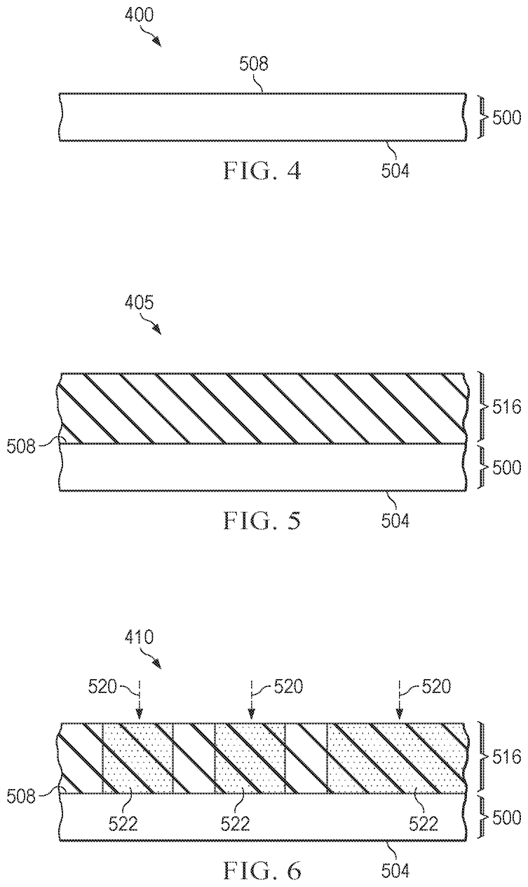

FIGS. 4-15 illustrate stages of a method for fabricating a wafer, such as the wafer 200 of FIG. 2 and/or the wafer 300 of FIG. 3. The method is implemented with wafer level processing. For purposes of simplification, FIGS. 4-15 employ the same reference numbers to denote the same structures.

As illustrated in FIG. 4, in a first stage 400 of the method, a wafer 500 is provided. In some examples, the wafer 500 includes a circuitry module for dies (e.g., the circuit module 140 of FIGS. 1A and 1B) and a surface for mounting the dies. More specifically, the wafer 500 includes a first surface 504 that is employable for grinding and/or providing an area for mounting dies. The wafer 500 also includes a second surface 508 that opposes the first surface 504. The second surface 508 includes regions (e.g., exposed connections) for connecting to the circuit modules for dies.

As illustrated in FIG. 5, in a second stage 405 of the method, a selective polyimide film 516 is applied to the second surface 508 of the wafer 500. The selective polyimide film 516 is a polyimide film formed of a synthetic polymer with a stable and heat-resistant molecular structure. The selective polyimide film 516 is an insulative material.

As illustrated in FIG. 6, in a third stage 410 of the method, in a first exposure operation, a reticle image of a reticle is applied to the selective polyimide film 516. Portions not protected by the by the reticle are exposed to ultraviolet (UV) or deep ultraviolet (DUV) light that shone on the reticle image to an image on the selective polyimide film 516. In the example illustrated, arrows 520 indicate regions 522 of the selective polyimide film 516 that are exposed to the UV or DUV light in the first exposure operation.

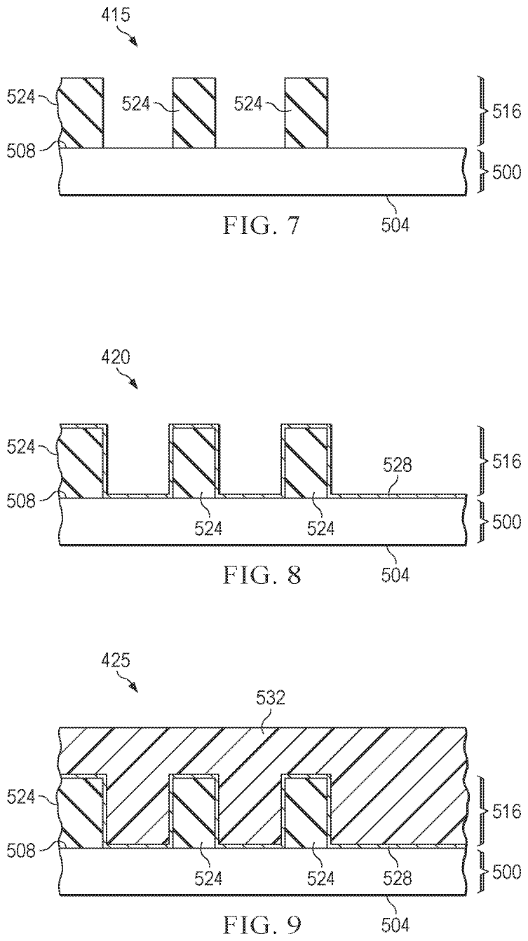

As illustrated in FIG. 7, in a fourth stage 415 of the method, in response to the first exposure operation, in a first development operation, the wafer (including the wafer 500 and the selective polyimide film 516) is immersed in a development solution to dissolve the regions (522 of FIG. 6) of the selective polyimide film 516 that were exposed to the UV or DUV light. The resultant structure has selective polyimide structures 524.

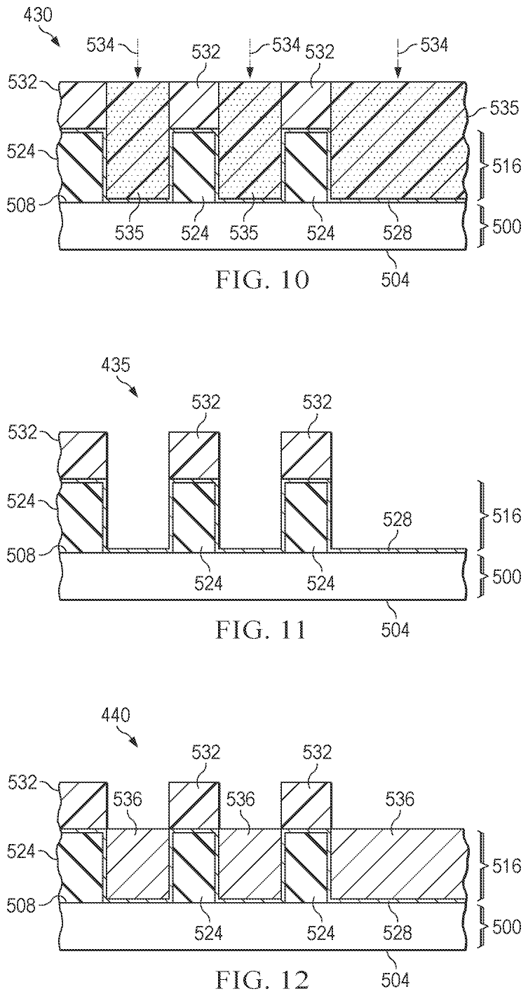

As illustrated in FIG. 8, in a fifth stage 420 in a metal sputtering operation, a layer of metal (referred to as a metal layer 528) is applied over the selective polyimide structures 524 and over exposed regions of the wafer 500. As illustrated in FIG. 9, in a sixth stage 425 in a coating operation, a layer of photoresist 532 (PR) is applied over the metal layer 528.

As illustrated in FIG. 10, in a sixth stage 430 of the method, in a second exposure operation, regions of the photoresist 532 are exposed to UV or DUV light. In some examples, the same reticle image is applied to the wafer as is used for the first exposure operation at 410. In the example illustrated, arrows 534 indicate regions 535 of the selective polyimide film 516 that are exposed to the UV or DUV light in the second exposure operation. As illustrated in FIG. 11 in a seventh stage 435 of the method, in a second development operation, in response to the second exposure operation, the wafer is immersed in a development solution to dissolve the regions (535 of FIG. 11) of the photoresist 532 that were exposed to the UV or DUV light in the second exposure operation.

As illustrated in FIG. 12, in an eighth stage 440 of the method, in an electroplating operation (BOAC plating in some examples), layers of metal 536 are deposited where the photoresist 532 has been removed. The layers of metal 536 are copper (Cu), nickel (Ni) and palladium (Pd) in one example. That is, the copper (Cu), nickel (Ni) and palladium (Pd) are deposited in regions where the photoresist 532 has been removed. In another example, copper (Cu) is deposited in the regions where the photoresist 532 has been removed. In other examples, the there are other metals employed.

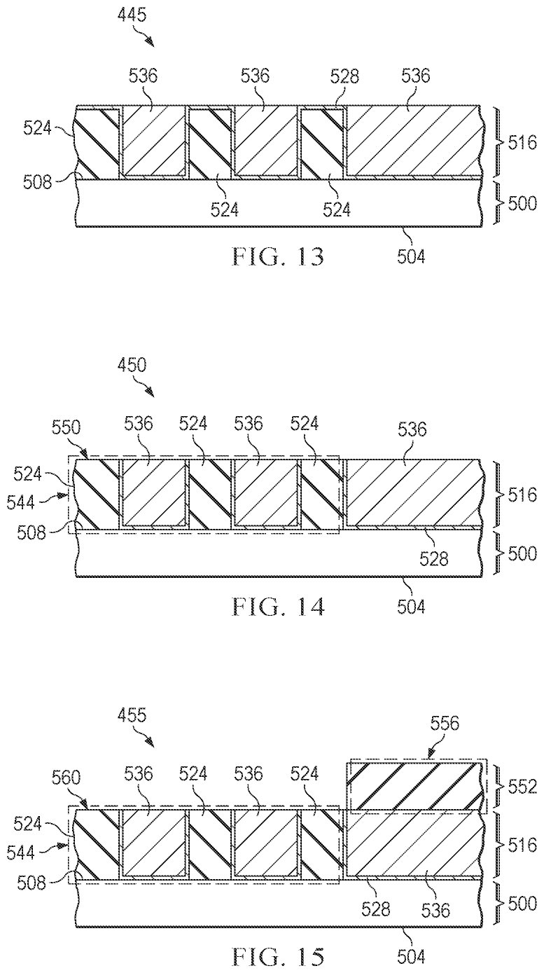

As illustrated in FIG. 13, in a ninth stage 445 of the method, in a stripping operation, remaining portions of the photoresist 532 of FIG. 12 are stripped off the selective polyimide structures 524. In some examples, the stripping is a wet stripping executed with a solvent, a sulfuric acid solution or alkaline stripping. In other examples, the stripping is a dry stripping with plasma. In yet other examples, the stripping is a mechanical stripping or a UV stripping. In any such example, the resultant structure has portions of the metal layer 528 overlaying the selective polyimide structures 524.

As illustrated in FIG. 14, in a tenth stage 450 of the method, in an etching operation the portions of the metal layer 528 overlaying the selective polyimide structures 524 are removed (through the etching). The resultant wafer 550 has a planar region, the selective polyimide structures 524 between contact points of a connection pad, which connection points are implemented with the layers of metal 536 or some portion thereof. Moreover, the resultant wafer 550 has a planar surface, including a planar region 544 for a connection pad. Thus, the resultant wafer 550 is employable to implement the wafer 200 of FIG. 2.

As illustrated in FIG. 15, in an eleventh stage 455 of the method, the selective polyimide film 516 is a first selective polyimide film. Additionally, in the eleventh stage, a second selective polyimide film 552 is applied to a region of the planar surface that is spaced apart from the planar region 544 to form a non-planar region 556. Thus, the resultant wafer 560 includes both the planar region 544 and the non-planar region 556. Accordingly, the resultant wafer 560 is employable to implement the wafer 300 of FIG. 3.

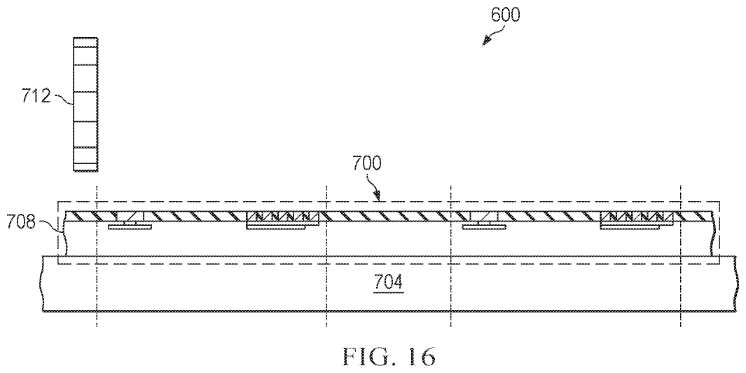

FIGS. 16, 17A, 17B, 18A, 18B and 19 illustrate stages of a method for fabricating an IC package, such as the IC package 100 of FIGS. 1A and 1B. The method is implemented with package level processing. Thus, FIGS. 16, 17A, 17B, 18A, 18B and 19 employ the same reference numbers to denote the same structure. Moreover, the method illustrated in FIGS. 16, 17A, 17B, 18A, 18B and 19 can be executed in response to execution of the method illustrated in FIGS. 4-15. Thus, in some examples, FIGS. 4-16, 17A, 17B, 18A, 18B and 19 are considered to show different stages of the same method, which includes both wafer-level processing, as illustrated in FIGS. 4-15 and package-level processing, as illustrated in FIGS. 16, 17A, 17B, 18A, 18B and 19.

As illustrated in FIG. 16, in a first stage 600 of the method, a wafer 700 is situated on a dicing table 704. The wafer 700 includes K number of dies 708, where K is an integer greater than or equal to one. Each die 708 is employable to implement the die 108 of FIGS. 1A and 1B. In some examples, the wafer 700 is implemented with the wafer 560 of FIG. 15. A saw 712, such as a laser saw, a diamond saw or a plasma cutter singulates the K number of dies 708.

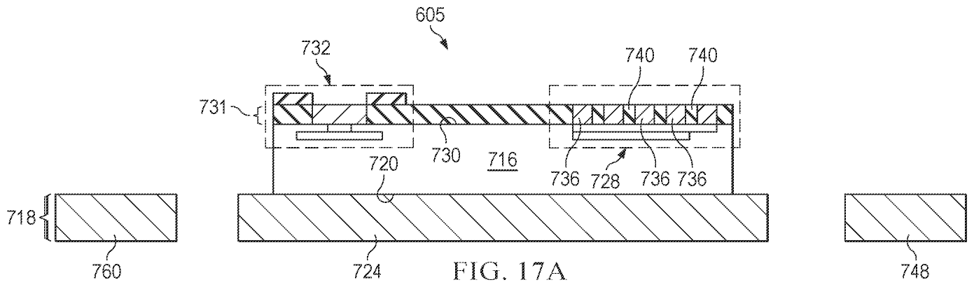

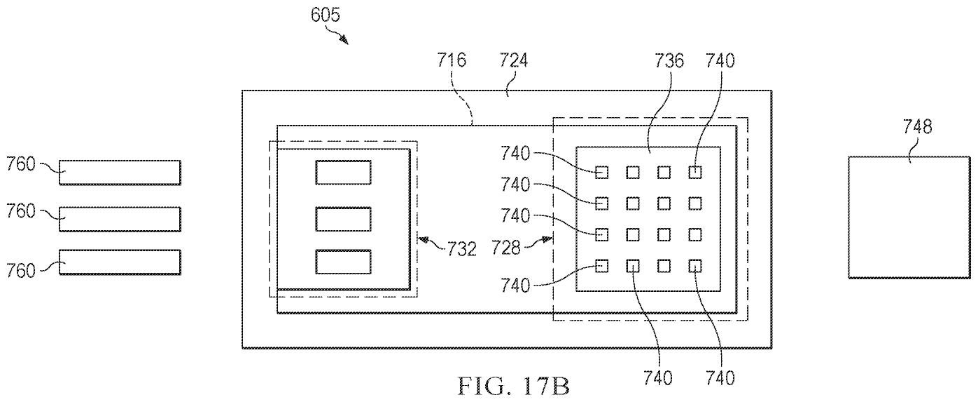

As illustrated in FIGS. 17A and 17B, in a second stage 605 of the method, a die 716 is mounted on an interconnect 718 (e.g., a lead frame). The die 716 is a given singulated die of the K number of dies 708 of FIG. 16. More particularly, a first surface 720 of the die 716 is mounted on a die attached pad 724 of the interconnect 718.

The die 716 includes a first connection pad 728 on a second surface 730 of the die 716 that is employable to implement the connection pad 104 of FIGS. 1A and 1B. The second surface has a selective polyimide film 731. The second surface 730 of the die 716 also includes a set of connection pads 732 that are employable to implement the connection pads 164 of the wire bond region 156 of FIGS. 1A and 1B. Thus, the first connection pad 728 has a planar surface formed with metal connection points 736 in a cross-hatch pattern and selective polyimide structures 740 (formed from the selective polyimide film 731) in between the metal connection points 736, as illustrated in FIG. 17B. Moreover, the first connection pad 728 provides a planar region of the first surface 720 and the set of connection pads 732 provides a non-planar region of the first surface 720.

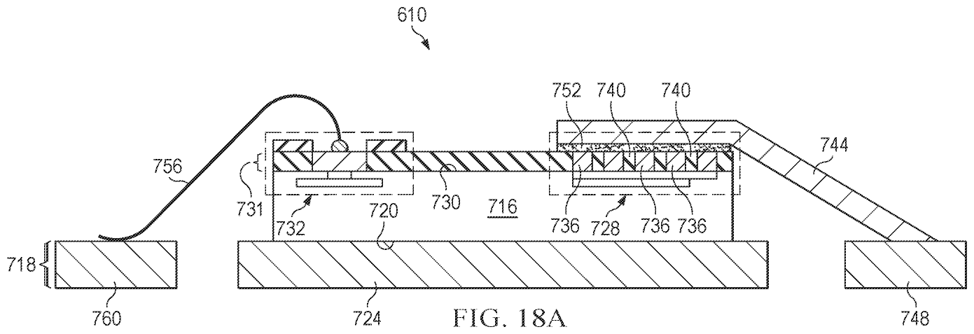

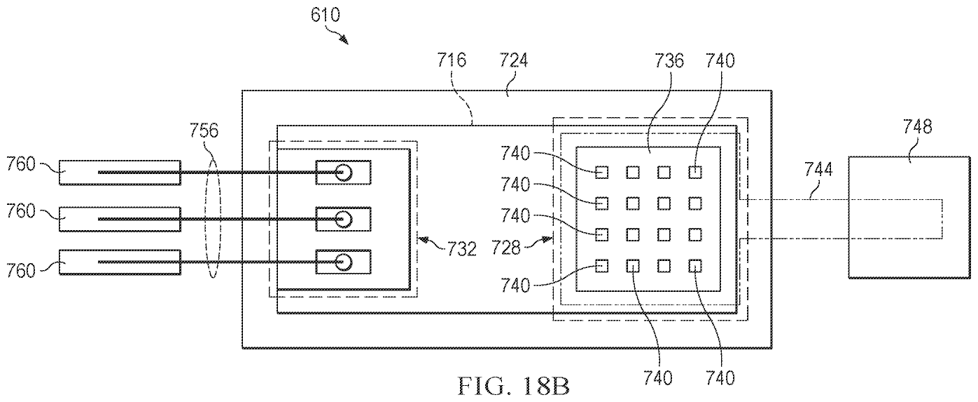

As illustrated in FIGS. 18A and 18B, in a third stage 610 of the method, a clip 744 is mounted on the first connection pad 728 and a first lead 748 of the interconnect 718. A conductive adhesive 752 (e.g., solder paste) is employed to adhere the clip 744 to the first connection pad 728. The planar surface provided by the combination of the metal connection points 736 and the selective polyimide structures 740 of the first connection pad 728 ensures relatively even distribution of the conductive adhesive 752. Additionally, in the third stage 610, wire bonds 756 are attached to the set of connection pads 732 and to leads 760 of the interconnect 718. The leads 760 are low power leads (e.g., 100 V or less) and the first lead 748 is a high power lead, such as for connections of 640 V or less. Thus, in some examples, the first connection pad 728 is connected to a drain or a source of FET of the die 716 to provide a high power connection to the first lead 748.

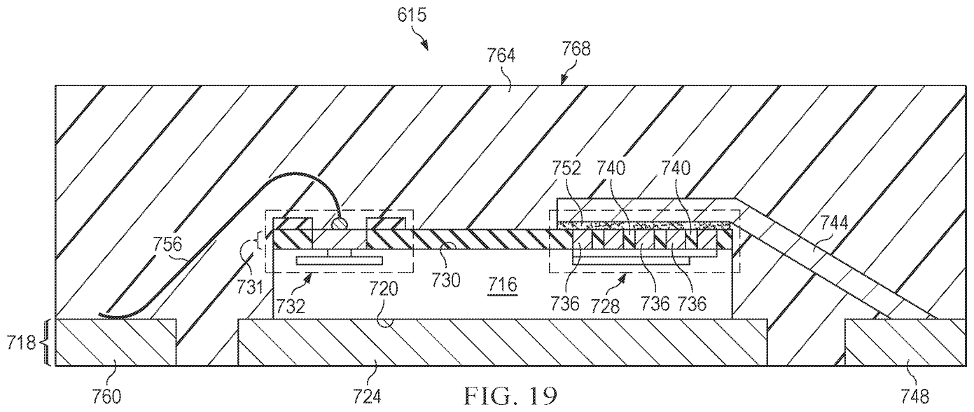

As illustrated in FIG. 19, in a fourth stage 615 of the method, a mold compound 764 is flowed over the interconnect 718, the die 716, the clip 744 and the wire bonds 756 to encapsulate the components therein. In this manner, a resultant IC package 768 is employable to implement the IC package 100 of FIGS. 1A and 1B.

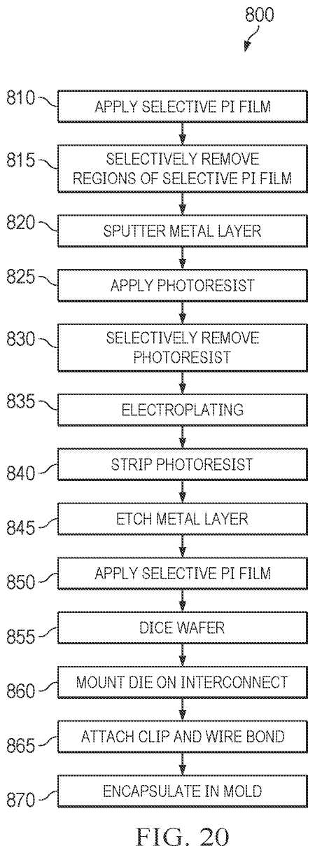

FIG. 20 is a flowchart of an example method 800 for forming an IC package, such as the IC package 100 of FIGS. 1A and 1B. At block 810 a coating of selective polyimide film (e.g., the selective polyimide film 516 of FIG. 5) is applied on a wafer (e.g., the wafer 500 of FIG. 4) with dies with a contact pad. At block 815, regions of the selective polyimide film are selectively removed to form selective polyimide structures (e.g., the selective polyimide structures 524 of FIG. 8). The removing of the regions of the selective polyimide includes exposing the regions of the selective polyimide film to ultraviolet light and immersing the wafer in a developer solution in response to the exposing.

At block 820 a metal layer (e.g., the metal layer 528 of FIG. 8) is sputtered on the wafer responsive to the selective removing of the regions of the selective polyimide film. At block 825, a photoresist coat (e.g., the photoresist 532 of FIG. 9) is applied on the metal layer. At block 830, portions of the photoresist coat are selectively removed to expose portions of the metal layer that overly the contact pad of the dies. The selective removing portions of the photoresist coat includes exposing the regions of the selective polyimide film to ultraviolet light and immersing the wafer in a developer solution in response to the exposing.

At block 835, the portions of the metal layer that overlay the contact pad of the dies are electrode plated to form contact points for connection pads for the dies of the wafer, such that selective polyimide structures are between the contact points of the connection pad of the dies. At block 840, a remainder of the photoresist coat is stripped. At block 845, portions of the metal layer that overlay the selective polyimide structures to provide a planar region for the dies of the wafer are etched to provide a wafer, such as the wafer 300 of FIG. 3. At block 850, a second layer (e.g., the second selective polyimide film 552 of FIG. 15) of polyimide is selectively applied to the wafer to provide a resultant wafer with a planar region that includes the connection pad and a non-planar region, such as the wafer 300 of FIG. 3.

At block 855, the wafer (e.g., the wafer 700 of FIG. 16) is diced with a saw (e.g., the saw 712 of FIG. 16) to provide singulated dies (e.g., the dies 716 of FIG. 16). At block 860, a given die of the singulated dies is mounted on a die attach pad (e.g., the die attached pad 724 of FIGS. 17A and 17B) of an interconnect (e.g., the interconnect 718 of FIGS. 17A and 17B). At block 865, a clip (e.g., the clip 744 of FIGS. 18A and 18B) and wire bonds (e.g., the wire bonds 756 of FIGS. 18A and 18B) are attached to connection pads of the die. The clip is adhered to the connection pad of the die with a conductive adhesive. The presence of the selective polyimide structures in the connection pad ensures that the conductive adhesive flows relatively evenly over the connection pad. At block 870, the resultant structure is encapsulated in a mold compound (e.g., the mold compound 764 of FIG. 19) to provide the IC package (e.g., the IC package 100 of FIGS. 1A and 1B).

In this description, unless otherwise stated, “about” preceding a parameter means being within +/−10 percent of that parameter. Modifications are possible in the described embodiments, and other embodiments are possible, within the scope of the claims.

What is claimed is:

1. An IC (integrated circuit) package comprising:
an interconnect having a die attach pad and leads;
a die comprising:
a first side mounted on the die attach pad; and
a second side opposing the first side, the second side having a planar region, the planar region having selective polyimide structures between contact points of a connection pad; and
a clip coupled to the connection pad and to a lead of the leads.

2. The IC package of claim 1, further comprising solder flowed over the selective polyimide structures and the contact points of the connection pad.

3. The IC package of claim 1, wherein the clip is attached to the connection points and the polyimide structures of the connection pad with a conductive adhesive.

4. The IC package of claim 3, wherein the planar region of the die is a first region, the second side of the die comprising a second region comprising a polyimide layer, wherein the second region is spaced apart from the first region.

5. The IC package of claim 4, wherein the connection pad is a first connection pad, the second region comprising a second connection pad.

6. The IC package of claim 5, wherein the lead of the leads of the interconnect is a first lead, the IC package further comprising a wire bond that couples the second connection pad to a second lead of the leads of the interconnect.

7. The IC package of claim 1, wherein the connection pad is coupled to a circuit embedded in the die.

8. The IC package of claim 7, wherein the connection pad is a BOAC (bond over active circuit) pad.

9. A wafer comprising:
dies having a first side and a second side opposing the first side, the second side of the dies having a planar region, the planar region having selective polyimide structures between contact points of a connection pad.

10. The wafer of claim 9, wherein the connection pad of the dies are BOAC (bond over active circuit) connection pads.

11. The wafer of claim 9, wherein the planar region of the dies is a first region, the second side the dies comprising a second region comprising a selective polyimide film, wherein the second region is spaced apart from the first region.

12. A method for forming an IC (integrated circuit) package comprising:
applying a coating of selective polyimide film on a wafer comprising dies with a contact pad;
selectively removing regions of the selective polyimide film to form selective polyimide structures;
sputtering a metal layer responsive to the selective removing of the regions of the selective polyimide film;
applying a photoresist coat on the metal layer;
selectively removing portions of the photoresist coat to expose portions of the metal layer that overly the contact pad of the dies;
electroplating the portions of the metal layer that overlay the contact pad of the dies to form contact points for connection pads for the dies of the wafer, such that selective polyimide structures are between the contact points of the connection pad of the dies;
stripping a remainder of the photoresist coat; and
etching portions of the metal layer that overlay the selective polyimide structures to provide a planar region for the dies of the wafer.

13. The method of claim 12, wherein the removing of the regions of the selective polyimide comprises exposing the regions of the selective polyimide film to ultraviolet light.

14. The method of claim 13, wherein the removing of the regions of the selective polyimide further comprises immersing the wafer in a developer solution responsive to the exposing.

15. The method of claim 12, wherein the selectively removing portions of the photoresist coat comprises exposing the regions of the selective polyimide film to ultraviolet light.

16. The method of claim 15, wherein the removing of the portions of the photoresist coat further comprises immersing the wafer in a developer solution responsive to the exposing.

17. The method of claim 12, wherein the electroplating comprises depositing copper, nickel and palladium on the portions of the metal layer that overlay the circuit connection regions to form the connection points for the contact pads of the dies of the wafer.

18. The method of claim 12, wherein the electroplating comprises depositing copper on the portions of the metal layer that overlay the circuit connection regions to form connections pads for the wafer.

19. The method of claim 12, further comprising singulating the dies of the wafer.

20. The method of claim 18, further comprising:
mounting a given die of the dies to an interconnect; and
attaching a clip overlaying the planar region of the given die to a lead of the interconnect.
